(19) United States
(12) Patent Application Publication
(10) Pub. No.: US 2026/0186078 A1
(43) Pub. Date: Jul. 2, 2026

(54) IN-FIELD ADVANCED INTERCONNECT VERIFY SCHEME

(71) Applicant: Micron Technology, Inc., Boise, ID (US)

(72) Inventors: Chong Giap Chiew, San Jose, CA (US); Jun Xu, San Jose, CA (US); Massimo Rossini, Roma (IT); Alessandro Martini, Fontechiari (IT); Eleuterio Mannella, L'aquila (IT)

(21) Appl. No.: 19/415,364

(22) Filed: Dec. 10, 2025

Related U.S. Application Data
(60) Provisional application No. 63/739,881, filed on Dec. 30, 2024.

(51) Int. Cl. G01R 31/70; G01R 19/00; G01R 19/165; G01R 27/14; G01R 31/52; H10P 74/20; H10W 72/90

(52) U.S. Cl. CPC G01R 31/70; G01R 19/0038; G01R 19/1659; G01R 27/14; G01R 31/52; H10P 74/207; H10W 72/967

(57) ABSTRACT

In-field advanced interconnect verify schemes are disclosed herein. In some embodiments, a system includes first dummy pads, second dummy pads, a current source, a comparator, current source access (CSA) transistors, and comparator access (CA) transistors. The first dummy pads can be electrically connected in series to form a first chain. The second dummy pads can be electrically connected in series to form a second chain. The CSA transistors can selectively couple the current source to a first end of the first chain, a first end of the second chain, a second end of the first chain, and a second end of the second chain. The CA transistors can selectively couple an input of the comparator to the first end of the first chain, the first end of the second chain, the second end of the first chain, and the second end of the second chain.

### CROSS-REFERENCE TO RELATED APPLICATION(S)

The present application claims priority to U.S. Provisional Patent Application No. 63/739,881, filed Dec. 30, 2024, the disclosure of which is incorporated herein by reference in its entirety.

### TECHNICAL FIELD

The present technology generally relates to semiconductor device assemblies, and more particularly relates to in-field advanced interconnect verify schemes.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

Features, aspects, and advantages of the presently disclosed technology may be better understood with regard to the following drawings.

FIG. 1 is a partially schematic diagram of a semiconductor interconnect verification system configured in accordance with embodiments of the present technology.

FIG. 2 is a partially schematic diagram of another semiconductor interconnect verification system configured in accordance with embodiments of the present technology.

FIG. 3 is a timing diagram illustrating a method for verifying circuit resistivity in accordance with embodiments of the present technology.

FIG. 4 is a flowchart illustrating a method for testing resistivity of bonding between a first wafer and a second wafer in accordance with embodiments of the present technology.

FIG. 5 is a timing diagram illustrating a method for verifying circuit leakage in accordance with embodiments of the present technology.

FIG. 6 is a flowchart illustrating a method for testing for leakage in bonding between a first wafer and a second wafer in accordance with embodiments of the present technology.

FIG. 7 is a timing diagram illustrating a method for verifying circuit shorts in accordance with embodiments of the present technology.

FIG. 8 is a flowchart illustrating a method for testing for short circuiting in bonding between a first wafer and a second wafer in accordance with embodiments of the present technology.

FIG. 9 is an enlarged view of misaligned dummy pads that can be included in the semiconductor interconnect verification system of FIG. 2.

FIG. 10 illustrates a graphical user interface that can configure the semiconductor interconnect verification system usage in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

### I. Overview

Embodiments of the present technology are directed to semiconductor interconnect verification systems and associated devices and methods. NAND flash memory and other semiconductor devices can include wafer-over-wafer (WoW) bonding, such as between an array wafer and a complementary metal-oxide-semiconductor (CMOS) wafer, to support the increasing complexity and density of semiconductor devices. However, the WoW bonding can become compromised as the semiconductor device undergoes various physical, thermal, soldering, and/or other stresses during packaging and other processes. For example, the interconnect pads that form the WoW bonding can be vulnerable to various defects such as forming poor contacts, having resistive materials therebetween, misalignment, short-circuiting, and/or the like. With the number of interconnect pads increasing and the sizes thereof decreasing, there is a need for a system or method that can efficiently detect any potential defects in and verify the integrity of semiconductor devices, such as ones having WoW bonding.

Embodiments of the present technology address at least some of the above described issues for testing interconnect pads. For example, embodiments of the present disclosure include a semiconductor interconnect verification system for testing bonding between a first wafer and a second wafer. The system can include a plurality of first dummy pads, a plurality of second dummy pads, a current source, a comparator, a plurality of current source access (CSA) transistors, and a plurality of comparator access (CA) transistors. The first dummy pads can be electrically connected to one another in series to form a first chain. The first dummy pads can be arranged in pairs including a top dummy pad coupled to the first wafer and a bottom dummy pad coupled to the second wafer. The second dummy pads can be electrically connected to one another in series to form a second chain. The second dummy pads can be arranged in pairs including a top dummy pad coupled to the first wafer and a bottom dummy pad coupled to the second wafer. The current source can be configured to generate a current. The comparator can have a first input coupled to receive a ramp signal and a second input.

The plurality of CSA transistors can include (i) a first CSA transistor selectively coupling the current source to a first end of the first chain, (ii) a second CSA transistor selectively coupling the current source to a first end of the second chain, (iii) a third CSA transistor selectively coupling the current source to a second end of the first chain, and (iv) a fourth CSA transistor selectively coupling the current source to a second end of the second chain. The plurality of CA transistors can include a (i) first CA transistor selectively coupling the second input of the comparator to the first end of the first chain, (ii) a second CA transistor selectively coupling the second input of the comparator to the first end of the second chain, (iii) a third CA transistor selectively coupling the second input of the comparator to the second end of the first chain, and (iv) a fourth CA transistor selectively coupling the second input of the comparator to the second end of the second chain.

In some embodiments, a method for testing resistivity of bonding between a first wafer and a second wafer can include (i) providing a first chain and a second chain, (ii) determining a voltage drop across the first chain, and (iii) comparing the determined voltage drop across the first chain against a lower threshold value and an upper threshold value. If the determined voltage drop is between the lower threshold value and the upper threshold value, comparing can comprise determining that the first chain is neither open nor short-circuited. If the determined voltage drop is below the lower threshold value, comparing can comprise determining that the first chain is short-circuited. If the determined voltage drop is above the upper threshold value, comparing can comprise determining that the first chain is open.

In some embodiments, a method for testing for leakage in bonding between a first wafer and a second wafer can include (i) providing a first chain and a second chain, (ii) determining a voltage level retained by the first chain, and (iii) comparing the determined voltage level retained by the first chain against a threshold value. If the determined voltage level is below the threshold value, comparing can comprise determining that the first chain has a leakage. If the determined voltage level is above the threshold value, comparing can comprise determining that the first chain does not have a leakage.

In some embodiments, a method for testing for short circuiting in bonding between a first wafer and a second wafer can include (i) providing a first chain and a second chain, (ii) determining a voltage level of the second chain, and (iii) comparing the determined voltage level of the second chain against a threshold value. If the determined voltage level is below the threshold value, comparing can comprise determining that the first chain and the second chain are not short-circuited. If the determined voltage level is above the threshold value, comparing can comprise determining that the first chain and the second chain are short-circuited.

Embodiments of the present technology provide a single circuit layout that can be used to perform multiple different verification tests quickly and sequentially as desired. A user can apply various inputs according to a lookup table to easily choose between the different tests and/or change current flow paths. Also, the twisting or alternating arrangement of the dummy pads can enable the detection of short circuiting (or other issues) in multiple different directions, such as along a row, along a column, or diagonally. The results of the various verification tests can be used to quantify or otherwise gauge degradation of the WoW bonding or contact.

Also, the semiconductor interconnect verification system described herein are scalable and can be used to enable a smaller or a greater total number of verification tests. For example, in some embodiments, the system can include more than two chains (and more associated dummy pads) and more transistors. Each chain can include any number of dummy pads. Different chains can include the same number of dummy pads or different numbers of dummy pads.

In the Figures, identical reference numbers identify generally similar, and/or identical, elements. Many of the details, dimensions, and other features shown in the Figures are merely illustrative of particular embodiments of the disclosed technology. Accordingly, other embodiments can have other details, dimensions, and features without departing from the spirit or scope of the disclosure. In addition, those of ordinary skill in the art will appreciate that further embodiments of the various disclosed technologies can be practiced without several of the details described below.

### II. Selected Embodiments of Semiconductor Interconnect Verification Systems

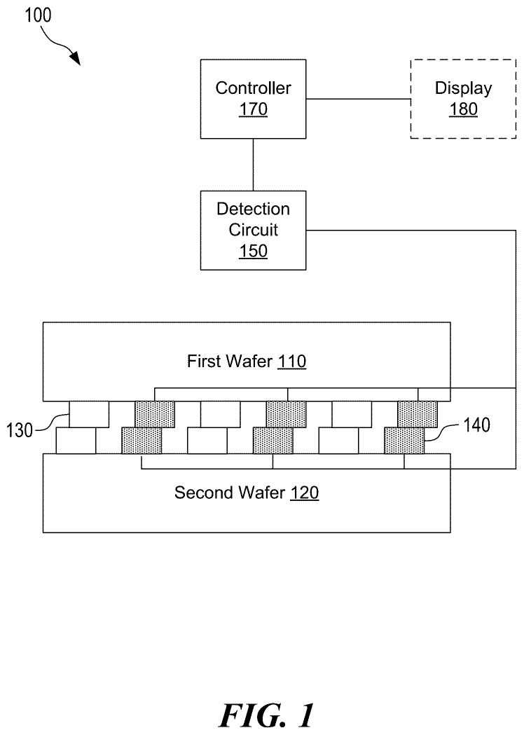

FIG. 1 is a partially schematic diagram of a semiconductor interconnect verification system 100 (“system 100”) configured in accordance with embodiments of the present technology. The system 100 can include a first wafer 110 (e.g., an array wafer), a second wafer 120 (e.g., a CMOS wafer), a detection circuit 150, and a controller 170. The first wafer 110 and the second wafer 120 can be bonded together via WoW bonding. As shown, the first wafer 110 and the second wafer 120 can each include a plurality of true pads 130 and a plurality of dummy pads 140 (patterned for illustrative purposes only). The true pads 130 and the dummy pads 140 can be arranged adjacent to one another, in an alternating manner, interspersed, and/or in other configurations. The true pads 130 and the dummy pads 140 can be composed of copper or other suitable material. The true pads 130 of the first wafer 110 can be connected to corresponding ones of the true pads 130 of the second wafer 120 in pairs, and the dummy pads 140 of the first wafer 110 can be connected to corresponding ones of the dummy pads 140 of the second wafer 120 in pairs.

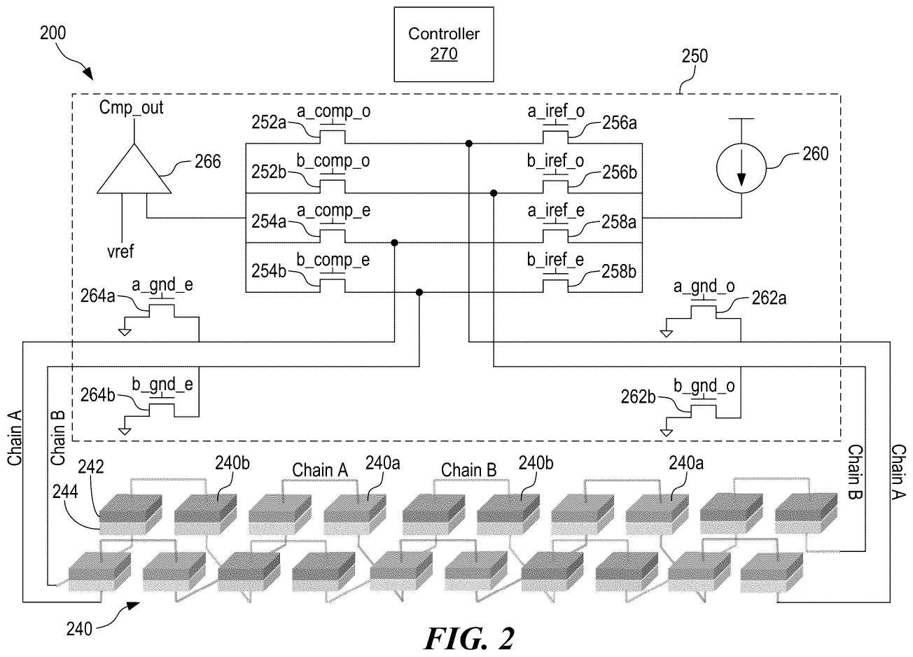

The true pads 130 can be electrically connected to other components in the first wafer 110 and/or the second wafer 120 (e.g., integrated circuits thereof) and can function as conventional WoW pads that serve as the necessary interconnects between the first wafer 110 and the second wafer 120. On the other hand, the dummy pads 140 may not be connected to other components in the first wafer 110 and/or the second wafer 120, and instead can be connected to the detection circuit 150. The detection circuit 150 can include various components (e.g., comparators, current sources, transistors, switches) that can be controlled by the controller 170 to test the dummy pads 140 for various defects. Example arrangements and methods of operation of the dummy pads 140 and the detection circuit 150 are described in further detail below with reference to FIGS. 2-10.

The controller 170 can be operated and/or programmed to control various components of the detection circuit 150. For example, the controller 170 can transmit control signals for controlling switches, transistors, and/or the like. The controller 170 can also process the outputs of the detection circuit 150 and communicate the results. For example, in some embodiments, the controller 170 can generate a graphical user interface, displayable on a display 180, that visually indicates to a user what types of defects, if any, were detected among the dummy pads 140 using the detection circuit 150. One or more defects detected among the dummy pads 140 can indicate the presence of one or more corresponding defects among the true pads 130. Therefore, the system 100 can be used to efficiently determine whether there may be any potential defects in the WoW bonding without affecting functionality of the true pads 130.

FIG. 2 is a partially schematic diagram of another semiconductor interconnect verification system 200 (“system 200”) configured in accordance with embodiments of the present technology. The system 200 can be an example of the system 100 of FIG. 1, and similarly numbered components can be similar in structure and/or function. For example, the system 200 can include a plurality of dummy pads 240, a detection circuit 250, and a controller 270.

The dummy pads 240 can be grouped into a first group of dummy pads 240a (“first dummy pads 240a”) that form a first chain (“Chain A”) and a second group of dummy pads 240b (“second dummy pads 240b”) that form a second chain (“Chain B”). The first dummy pads 240 a can be electrically coupled to one another, and the second dummy pads 240b can be electrically coupled to one another. Also, Chain A and Chain B can be configured at the manufacturing stage such that the first dummy pads 240a are electrically isolated from the second dummy pads 240b (although, as discussed further herein, the first dummy pads 240a and the second dummy pads 240b may come into electrical contact, resulting in a defect). Furthermore, the dummy pads 240 are arranged in pairs including a top dummy pad 242 included in or attached to a first wafer (e.g., the first wafer 110 of FIG. 1; not shown in FIG. 2) and a bottom dummy pad 244 included in or attached to a second wafer (e.g., the second wafer 120 of FIG. 1; not shown in FIG. 2).

In the illustrated embodiment, Chain A and Chain B are arranged in a twisting, alternating, or checkerboard pattern such that first and second pairs of first dummy pads 240a are arranged adjacent to one another in a first row, third and fourth pairs of first dummy pads 240a are arranged adjacent to one another in a second row, fifth and sixth pairs of first dummy pads 240a are arranged adjacent to one another in the first row, and so forth. In an analogous manner, first and second pairs of second dummy pads 240b are arranged adjacent to one another in the second row, third and fourth pairs of second dummy pads 240b are arranged adjacent to one another in the first row, fifth and sixth pairs of second dummy pads 240b are arranged adjacent to one another in the second row, and so forth. Also, for both the first dummy pads 240a and the second dummy pads 240b, the second pair can be electrically coupled to the third pair (e.g., via a wire extending across the first and second rows), the fourth pair can be electrically coupled to the fifth pair, and so forth. As described in further detail herein, arranging Chain A and Chain B in the illustrated alternating pattern can enable the detection of short-circuiting, among other defects, in multiple different directions. Also, each of Chain A and Chain B includes a total of 20 (10 pairs) of dummy pads 240 in FIG. 2. In other embodiments, however, Chain A and Chain B can include a different number of pairs of dummy pads 240, and the first dummy pads 240a and the second dummy pads 240b can be arranged differently.

The detection circuit 250 can include a current source 260, a comparator 266, and a plurality of transistors. Specifically, the detection circuit 250 can include a first comparator access (CA) transistor 252a, a second CA transistor 252b, a third CA transistor 254a, a fourth CA transistor 254b, a first current source access (CSA) transistor 256a, a second CSA transistor 256b, a third CSA transistor 258a, and a fourth CSA transistor 258b. In the illustrated embodiment, the following four pairs of transistors are coupled in parallel between the current source 260 and a first input of the comparator 266, and the two transistors of each pair are coupled in series: (i) the transistor 252a and the transistor 256a, (ii) the transistor 252b and the transistor 256b, (iii) the transistor 254a and the transistor 258a, and (iv) the transistor 254b and the transistor 258b.

Also, a first end of Chain A can be coupled to a node between the transistor 252a and the transistor 256a, a first end of Chain B can be coupled to a node between the transistor 252b and the transistor 256b, a second end of Chain A can be coupled to a node between the transistor 254a and the transistor 258a, and a second end of Chain B can be coupled to a node between the transistor 254b and the transistor 258b. Therefore, the transistors 252a, 254a can selectively couple Chain A to the first input of the comparator 266, the transistors 252b, 254b can selectively couple Chain B to the first input of the comparator 266, the transistors 256a, 258a can selectively couple Chain A to the current source 260, and the transistors 256b, 258b can selectively couple Chain B to the current source 260.

The detection circuit 250 can further include a first ground access (GA) transistor 262a, a second GA transistor 262b, a third GA transistor 264a, and a fourth GA transistor 264b. The transistor 262a can selectively couple the first end of Chain A to ground, the transistor 262b can selectively couple the first end of Chain B to ground, the transistor 264a can selectively couple the second end of Chain A to ground, and the transistor 264b can selectively couple the second end of Chain B to ground. A second input of the comparator 266 can be coupled to receive a ramp signal vref, and the comparator 266 can output a comparator output Cmp_out.

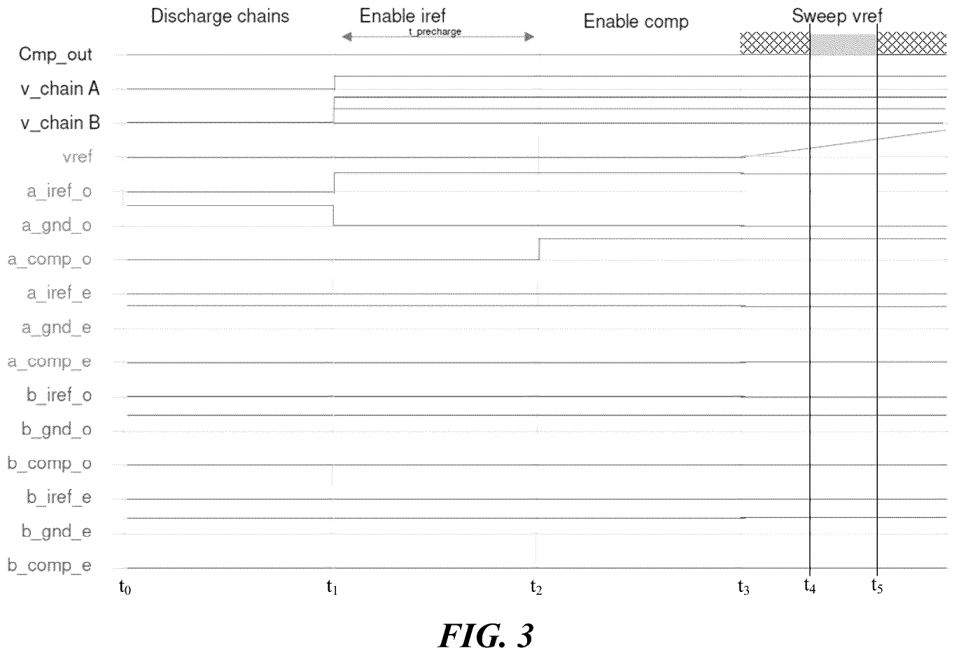

As discussed in further detail with reference to FIGS. 3-5, the controller 270 can selectively activate and deactivate one or more of the transistors of the detection circuit 250 (e.g., by sending control signals to the gate terminals of the transistors) to test Chain A and Chain B for different defects. As shown in FIG. 2, and for purposes of discussion of FIGS. 3-5, the transistor 252a can be controlled by control signal a_comp_o, the transistor 252b can be controlled by control signal b_comp_o, the transistor 254a can be controlled by control signal a_comp_e, the transistor 254b can be controlled by control signal b_comp_e, the transistor 256a can be controlled by control signal a_iref_o, the transistor 256b can be controlled by control signal b_iref_o, the transistor 258a can be controlled by control signal a_iref_e, and the transistor 258b can be controlled by control signal b_iref_e. The comparator output Cmp_out can be usable as a proxy to determine (i) a resistivity of, (ii) whether a leakage exists in, and (iii) whether a short exists in the bonding between the first wafer and the second wafer.

### III. Selected Embodiments of Methods for Verifying Interconnects

FIGS. 3-8 are various timing diagrams and flowcharts illustrating various tests for detecting different types of defects in the WoW bonding pads. While the timing diagrams and the flowcharts are discussed below with respect to the system 200 of FIG. 2, it will be appreciated that the timing diagrams illustrated and described herein can be applicable to other embodiments of semiconductor interconnect verification systems configured in accordance with embodiments of the present technology.

FIG. 3 is a timing diagram illustrating a method for verifying circuit resistivity in accordance with embodiments of the present technology. In particular, the illustrated timing diagram corresponds to verifying circuit resistivity in Chain A using a first current flow direction. As discussed further herein, the illustrated timing diagram can be modified to verify circuit resistivity in Chain A using a second current flow direction and/or in Chain B using the first or second current flow direction. In some embodiments, the controller 270 can be operated to assert or unassert the various control signals described herein.

At time t₀, a discharge period begins by asserting control signal a_gnd_o, a_gnd_e, b_gnd_o, and b_gnd_e, thus activating transistors 262a, 262b, 264a, 264b (FIG. 2). The remaining control signals are unasserted, thus deactivating the remaining transistors. Therefore, Chain A and Chain B can be coupled to ground on either end and electrically isolated from the current source 260 and the comparator 266, and can thus be discharged.

At time t₁, a precharge period begins by unasserting control signal a_gnd_o and asserting control signal a_iref_o, thus deactivating transistor 262a and activating transistor 256a. Therefore, a reference current I_{ref} generated by the current source 260 can flow through the transistor 256a, through Chain A and the first dummy pads 240a thereof, and to ground through the transistor 264a, which remains activated. Accordingly, the voltage drop across Chain A (“v_chain A” in FIG. 3) can rise to a certain level depending on the resistivity of Chain A and the reference current I_{ref}.

At time t₂, the control signal a_comp_o is asserted, thereby activating transistor 252a. Therefore, the voltage at the node between transistors 252a and 256a, which is the voltage drop across Chain A (v_chain A) can be applied to the first input of the comparator 266.

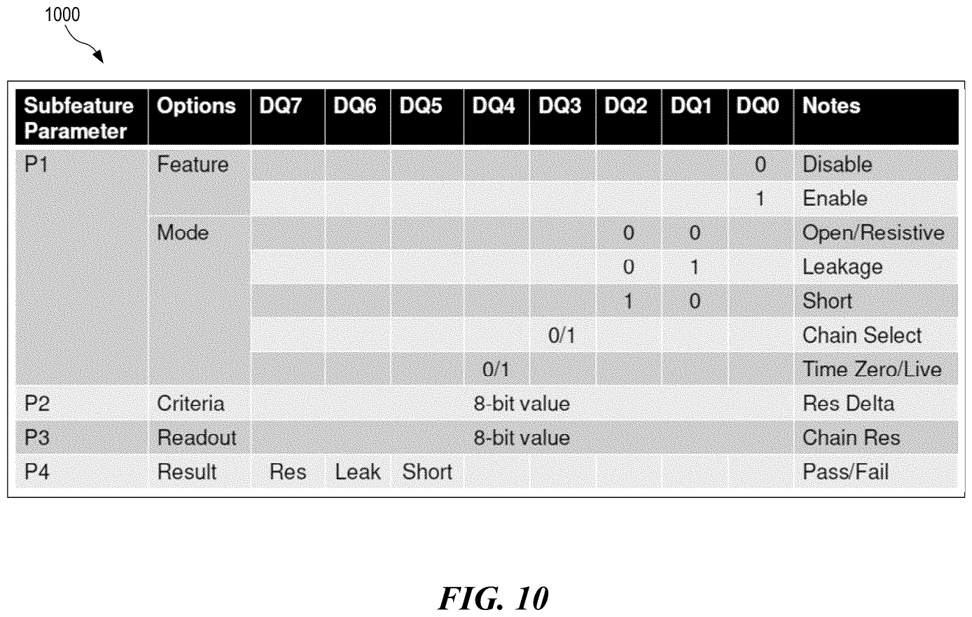

At time t₃, the ramp signal vref can be ramped as shown. The output of the comparator 266 Cmp_out will flip when vref matches v_chain A, allowing measurement of the voltage drop across Chain A. In some embodiments, Chain A passes the circuit resistivity test if the measured voltage drop across Chain A is between a lower threshold value and an upper threshold value, which, by virtue of the nature of the ramp signal vref, can correspond to times t₄ and t₅, respectively. The lower and upper threshold values can define the expected range of the voltage drop across Chain A if there are no issues. As discussed further herein with reference to FIG. 10, the lower and upper threshold values can be predetermined values stored in, e.g., a memory of the controller 270.

If Cmp_out flips between times t₄ and t₅, as indicated by a solid block in FIG. 3, then the measured voltage drop across Chain A is between the lower and upper threshold values, resulting in Chain A passing the circuit resistivity test for the first current direction. If Cmp_out flips before time t₄, as indicated by a patterned block in FIG. 3, then the measured voltage drop across Chain A is below the lower threshold value, resulting in Chain A failing the circuit resistivity test for the first current direction. In particular, if the measured voltage drop across Chain A is below the lower threshold value, this can indicate that there is a short (e.g., the current is not flowing through all of the first dummy pads 240a as expected) or there are other issues. If Cmp_out flips after time t₅, as indicated by another patterned block in FIG. 3, then the measured voltage drop across Chain A is above the upper threshold value, resulting in Chain A failing the circuit resistivity test for the first current direction. In particular, if the measured voltage drop across Chain A is above the upper threshold value, this can indicate that Chain A is open (e.g., a resistive material is stuck between the first dummy pads 240a) or has other issues. Therefore, the timing diagram of FIG. 3 can be used to verify circuit resistivity of Chain A using the first current direction.

While not explicitly illustrated, Chain A can be tested using the second current direction by, (i) at time t₁, asserting control signal a_iref_e instead of control signal a_iref_o, thereby activating transistor 258a instead of transistor 256a, (ii) at time t₁, unasserting control signal a_gnd_e instead of control signal a_gnd_o, thereby deactivating transistor 264a instead of transistor 262a, and (iii) at time t₂, asserting control signal a_comp_e instead of control signal a_comp_o, thereby activating transistor 254a instead of transistor 252a. Thus, the reference current I_{ref} generated by the current source 260 can flow through the transistor 258a, flow through the first dummy pads 240a from the second end of Chain A to the first end of Chain A, and to ground via the transistor 262a, which can remain activated.

Also while not explicitly illustrated, Chain B can be tested for circuit resistivity in a similar manner. For example, instead of asserting and/or unasserting the “a” control signals as described above, the “b” control signal counterparts can be asserted and/or unasserted instead. As described above with respect to Chain A, Chain B can be tested using two current directions. Therefore, the system 200 illustrated in FIG. 2 allows four unique circuit resistivity tests. A user can sequentially perform one or more of the unique circuit resistivity tests as needed.

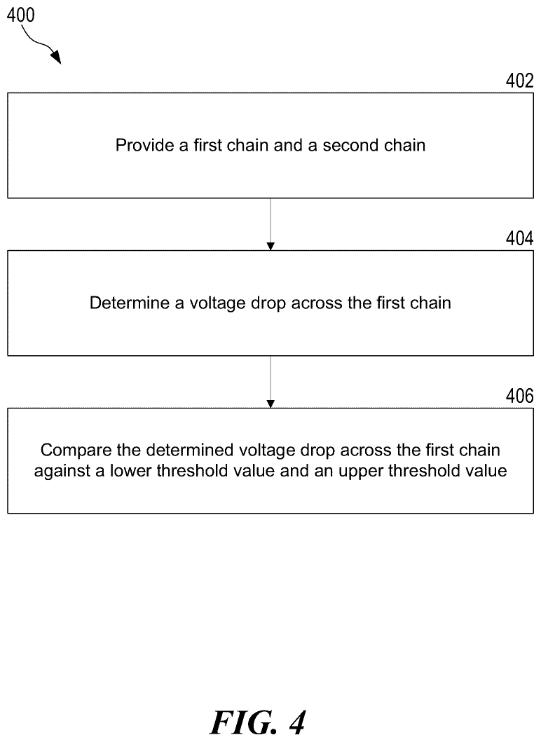

FIG. 4 is a flowchart illustrating a method 400 for testing resistivity of bonding between a first wafer and a second wafer in accordance with embodiments of the present technology. While the steps of the method 400 are described below in a particular order, one or more of the steps can be performed in a different order or omitted, and the method 400 can include additional and/or alternative steps. Additionally, although the method 400 may be described below with reference to the embodiments of the present technology described herein, the method 400 can be performed with other embodiments of the present technology.

The method 400 begins at block 402 by providing a first chain and a second chain. The first chain (e.g., Chain A of FIG. 2) can include a plurality of first dummy pads (e.g., the first dummy pads 240a) electrically connected to one another in series and to each of the first and second wafers (e.g., the first wafer 110 and the second wafer 120 of FIG. 1). The second chain (e.g., Chain B of FIG. 2) can include a plurality of second dummy pads (e.g., the second dummy pads 240b) electrically connected to one another in series and to each of the first and second wafers.

At block 404, the method 400 continues by determining a voltage drop across the first chain. Determining can include (i) activating a first one of four CSA transistors (e.g., the transistors 256a, 256b, 258a, 258b), (ii) activating a first one of four CA transistors (e.g., the transistors 252a, 252b, 254a, 254b), and (iii) applying a ramp signal (e.g., vref) to a second input of a comparator (e.g., the comparator 266). The voltage drop across the first chain can be determined based on an output of the comparator (e.g., Cmp_out).

At block 406, the method 400 continues by comparing the determined voltage drop across the first chain against a lower threshold value and an upper threshold value. The lower and upper threshold values can define the expected range of the voltage drop across the first chain if there are no issues. If the determined voltage drop is between the lower threshold value and the upper threshold value, comparing can comprise determining that the first chain is neither open nor short-circuited. If the determined voltage drop is below the lower threshold value, comparing can comprise determining that the first chain is short-circuited. If the determined voltage drop is above the upper threshold value, comparing can comprise determining that the first chain is open.

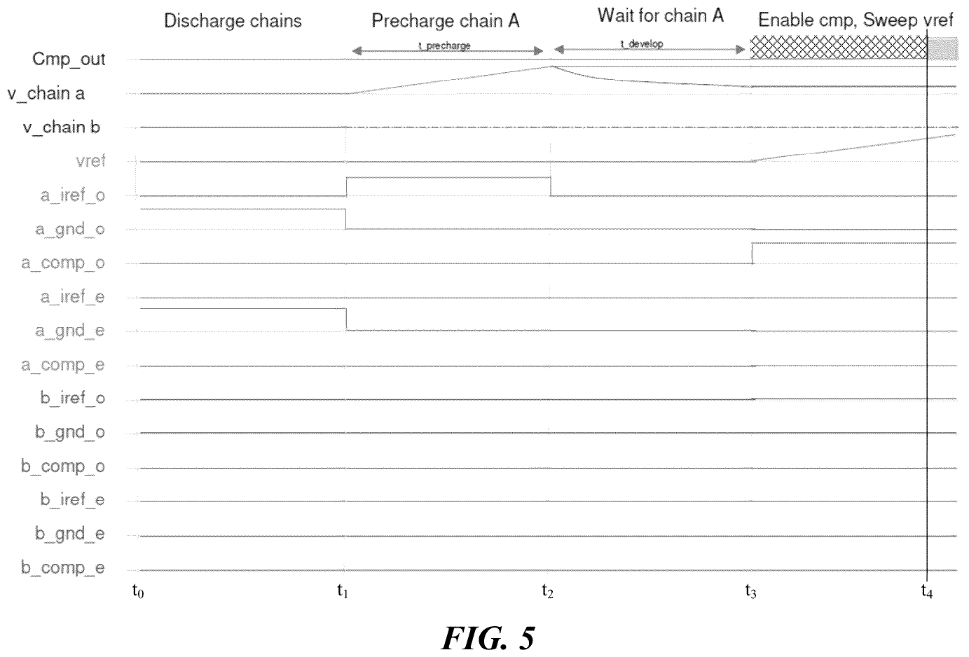

FIG. 5 is a timing diagram illustrating a method for verifying circuit leakage in accordance with embodiments of the present technology. In particular, the illustrated timing diagram corresponds to verifying circuit leakage in Chain A using a first current flow direction. As discussed further herein, the illustrated timing diagram can be modified to verify circuit leakage in Chain A using a second current flow direction and/or in Chain B using the first or second current flow direction. In some embodiments, the controller 270 can be operated to assert or unassert the various control signals described herein.

At time t₀, a discharge period begins by asserting control signal a_gnd_o and a_gnd_e, thereby activating transistors 262a and 264a. The remaining control signals are unasserted, thus deactivating the remaining transistors. Therefore, Chain A can be coupled to ground on either end and electrically isolated from the current source 260 and the comparator 266, and can thus be discharged. Notably, the control signals b_gnd_o and b_gnd_e can be unasserted, thereby deactivating transistors 262b and 264b. This can keep Chain B floating.

At time t₁, a precharge period begins by unasserting control signals a_gnd_o and a_gnd_e, and asserting control signal a_iref_o, thus deactivating transistors 262a and 264a, and activating transistor 256a. Therefore, a reference current I_{ref} generated by the current source 260 can flow through the transistor 256a and through Chain A and the first dummy pads 240a thereof. Because the second end of Chain A is neither grounded nor coupled to other components (only to deactivated transistors), the second end of Chain A is floating. Accordingly, Chain A can be pre-charged and the voltage level of Chain A (“v_chain a” in FIG. 5) can continuously rise, as shown, depending on the resistivity of Chain A and the reference current I_{ref}.

At time t₂, a waiting period begins by unasserting the control signal a_iref_o, thus deactivating transistor 256a. This results in both ends of Chain A floating. If there is no leakage from Chain A, Chain A can be expected to retain its voltage level and thus v_chain a can be expected to remain constant. If there is leakage from Chain A, Chain A can be expected to be unable to retain its voltage level and v_chain a can be expected to drop accordingly.

At time t₃, the control signal a_comp_o is asserted, thereby activating transistor 252a. Also, the ramp signal vref can be ramped as shown. The output of the comparator 266 Cmp_out will flip when vref matches v_chain a, allowing measurement of the voltage level retained by Chain A. In some embodiments, Chain A passes the circuit leakage test if the measured voltage level retained by Chain A is above a threshold value, which, by virtue of the nature of the ramp signal vref, can correspond to time t₄. The threshold value can define the minimum expected voltage level retained by Chain A if there are no leakage issues. As discussed further herein with reference to FIG. 10, the threshold value can be a predetermined value stored in, e.g., a memory of the controller 270.

If Cmp_out flips after time t₄, as indicated by a solid block in FIG. 5, then the measured voltage level retained by Chain A is above the threshold value, resulting in Chain A passing the circuit leakage test for the first current direction. If Cmp_out flips before time t₄, as indicated by a patterned block in FIG. 5, then the measured voltage level retained by Chain A is below the threshold value, resulting in Chain A failing the circuit leakage test for the first current direction. In particular, if the measured voltage level retained by Chain A is below the threshold value, this can indicate that there is a leakage in Chain A or other issues. Therefore, the timing diagram of FIG. 5 can be used to verify circuit leakage of Chain A using the first current direction.

While not explicitly illustrated, Chain A can be tested using the second current direction by, (i) at time t₁, asserting control signal a_iref_e instead of control signal a_iref_o, thereby activating transistor 258a instead of transistor 256a, (ii) at time t₂, unasserting control signal a_iref_e instead of control signal a_iref_o, thereby deactivating transistor 258a instead of transistor 256a, and (iii) at tie t₃, asserting control signal a_comp_e instead of control signal a_comp_o, thereby activating transistor 254a instead of transistor 252a. Thus, the reference current I_{ref} generated by the current source 260 can flow through the transistor 258a and the first dummy pads 240a from the second end of Chain A to the first end of Chain A.

Also while not explicitly illustrated, Chain B can be tested for circuit leakage in a similar manner. For example, instead of asserting and/or unasserting the “a” control signals as described above, the “b” control signal counterparts can be asserted and/or unasserted instead. As described above with respect to Chain A, Chain B can be tested using two current directions. Therefore, the system 200 illustrated in FIG. 2 allows four unique circuit leakage tests. A user can sequentially perform one or more of the unique circuit leakage tests as needed.

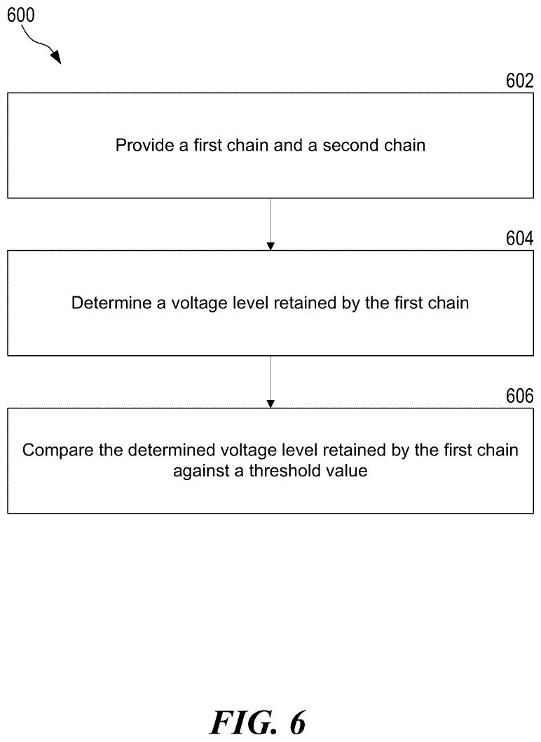

FIG. 6 is a flowchart illustrating a method for testing for leakage in bonding between a first wafer and a second wafer in accordance with embodiments of the present technology. While the steps of the method 600 are described below in a particular order, one or more of the steps can be performed in a different order or omitted, and the method 600 can include additional and/or alternative steps. Additionally, although the method 600 may be described below with reference to the embodiments of the present technology described herein, the method 600 can be performed with other embodiments of the present technology.

The method 600 begins at block 602 by providing a first chain and a second chain. The first chain (e.g., Chain A of FIG. 2) can include a plurality of first dummy pads (e.g., the first dummy pads 240a) electrically connected to one another in series and to each of the first and second wafers (e.g., the first wafer 110 and the second wafer 120 of FIG. 1). The second chain (e.g., Chain B of FIG. 2) can include a plurality of second dummy pads (e.g., the second dummy pads 240b) electrically connected to one another in series and to each of the first and second wafers.

At block 604, the method 600 continues by determining a voltage level retained by the first chain. Determining can include (i) activating a first one of four CSA transistors (e.g., the transistors 256a, 256b, 258a, 258b), (ii) deactivating the first CSA transistor, (iii) activating a first one of four CA transistors (e.g., the transistors 252a, 252b, 254a, 254b), and (iv) applying a ramp signal (e.g., vref) to a second input of a comparator (e.g., the comparator 266). The voltage level retained by the first chain can be determined based on an output of the comparator (e.g., Cmp_out).

At block 606, the method 600 continues by comparing the determined voltage level retained by the first chain against a threshold value. The threshold value can define the minimum expected voltage level retained by the first chain if there are no leakage issues. If the determined voltage level is below the threshold value, comparing can comprise determining that the first chain has a leakage. If the determined voltage level is above the threshold value, comparing can comprise determining that the first chain does not have a leakage.

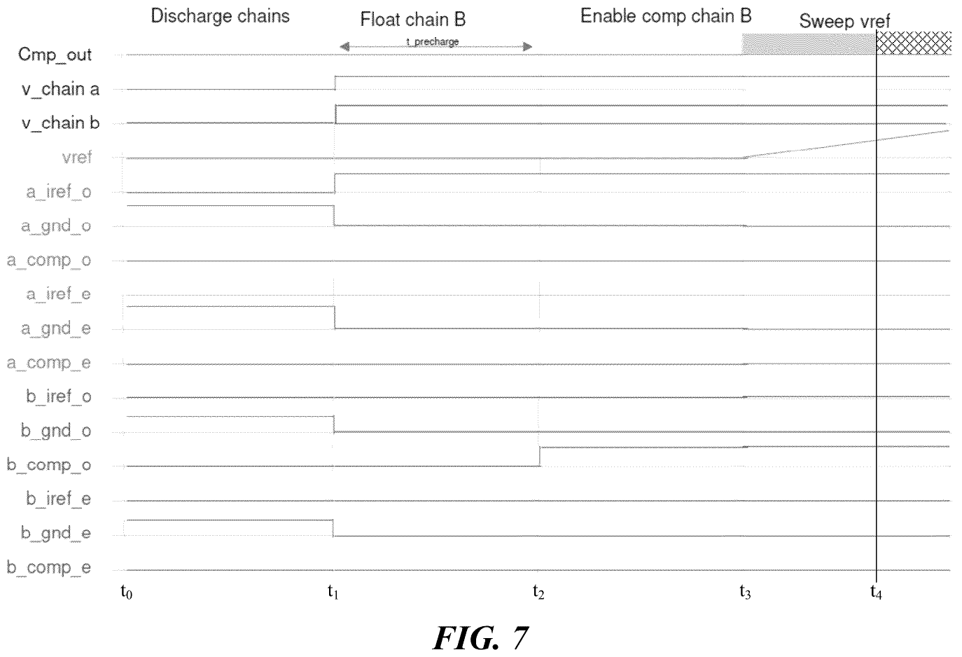

FIG. 7 is a timing diagram illustrating a method for verifying circuit shorts in accordance with embodiments of the present technology. In particular, the illustrated timing diagram corresponds to verifying circuit shorts between Chain A and Chain B by applying a current along a first current path. As discussed further herein, the illustrated timing diagram can be modified to verify circuit shorts between Chain A and Chain B by applying a current along one of three other current paths. In some embodiments, the controller 270 can be operated to assert or unassert the various control signals described herein.

At time t₀, a discharge period begins by asserting control signal a_gnd_o, a_gnd_e, b_gnd_o, b_gnd_e, thus activating transistors 262a, 262b, 264a, 264b. The remaining control signals are unasserted, thus deactivating the remaining transistors. Therefore, Chain A and Chain B can be coupled to ground on either end and electrically isolated from the current source 260 and the comparator 266, and can thus be discharged.

At time t₁, a floating period begins by (i) unasserting control signals a_gnd_o, a_gnd_e, b_gnd_o, b_gnd_e, thus deactivating transistors 262a, 262b, 264a, 264b, and (ii) asserting control signal a_iref_o, thereby activating transistor 256a. Therefore, both ends of Chain B and the second end of Chain A are configured to float during the floating period. A reference current I_{ref} generated by the current source 260 can flow through the transistor 256a and through Chain A and the first dummy pads 240a thereof. The voltage level of Chain A (“v_chain a” in FIG. 7) is expected to rise accordingly, as shown, depending on the resistivity of Chain A and the reference current I_{ref}.

At time t₂, the control signal b_comp_o is asserted, thus activating transistor 252b. Alternatively, in some embodiments, the control signal b_comp_e can be asserted instead, thus activating transistor 254b instead. Therefore, although the reference current I_{ref} is applied to one end of Chain A, the voltage level at one end of Chain B is measured using the comparator 266, as discussed further herein. If there is no short circuiting between Chain A and Chain B (e.g., none of the first dummy pads 240a contact any of the second dummy pads 240b), Chain B can be expected to have a relatively low voltage level (“v_chain b” in FIG. 7) because there should not be current flowing therethrough. If there is short circuiting between Chain A and Chain B (e.g., at least one of the first dummy pads 240a is in contact with at least one of the second dummy pads 240b), Chain B can be expected to have a relatively high voltage level because current is flowing from the first dummy pads 240a of Chain A to the dummy pads 240b of Chain B.

At time t₃, the ramp signal vref can be ramped as shown. The output of the comparator 266 Cmp_out will flip when vref matches v_chain b, allowing measurement of the voltage level of Chain B. In some embodiments, Chains A and B pass the circuit shorts test if the measured voltage level of Chain B is below a threshold value, which, by virtue of the nature of the ramp signal vref, can correspond to time t₄. The threshold value can define the maximum expected voltage level of Chain B if there are no short circuiting issues. As discussed further herein with reference to FIG. 10, the threshold value can be a predetermined value stored in, e.g., a memory of the controller 270.

If Cmp_out flips before time t₄, as indicated by a solid block in FIG. 7, then the measured voltage level of Chain B is below the threshold value, resulting in Chains A and B passing the circuit shorts test for the first current path. If Cmp_out flips after time t₄, as indicated by a patterned block in FIG. 7, then the measured voltage level of Chain B is above the threshold value, resulting in Chain A and Chain B failing the circuit shorts test for the first current path.

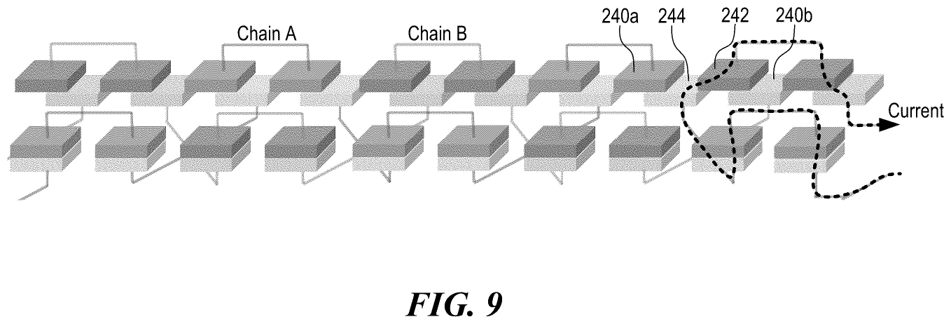

Referring momentarily to FIG. 9, FIG. 9 is an enlarged view of misaligned dummy pads 240 that can be included in the system 200. Specifically, in the illustrated embodiment, the top dummy pads 242 in the rear row of the dummy pads 240 are shifted to the left such that they are in electrical contact with the bottom dummy pads 244 to their left. If the dummy pads 240 are offset or misaligned as shown and the reference current I_{ref} is applied to one end of Chain A, the reference current I_{ref} (illustrated as a dashed arrow in FIG. 9) may flow from the bottom dummy pad 244 of the pair of first dummy pads labeled 240a to the top dummy pad 242 of the pair of second dummy pads labeled 240b. Thus, in the case of the illustrated dummy pad misalignment, the measured voltage level of Chain B can be above the threshold value, resulting in Chain A and Chain B failing the circuit shorts test for the first current path. Therefore, the timing diagram of FIG. 7 can be used to verify circuit shorts between Chain A and Chain B along the first current path. Notably, the twisting or alternating arrangement of Chain A and Chain B enable the detection of shorts in multiple different directions (e.g., along a row, along a column, diagonally).

While not explicitly illustrated, Chain A and Chain B can be tested along second, third, and fourth current paths by, at time t₁, instead of asserting control signal a_iref_o: (i) asserting control signal a_iref_e, thereby activating transistor 258a, (ii) asserting control signal b_iref_o, thereby activating transistor 256b, or (iii) asserting control signal b_iref_e, thereby activating transistor 258b. If an “a” control signal was asserted at time t₁, at time t₂, either control signal b_comp_o or control signal b_comp_e can be asserted, thereby activating transistor 252b or transistor 254b. If a “b” control signal was asserted at time t₁, at time t₂, either control signal a_comp_o or control signal a_comp_e can be asserted, thereby activating transistor 252a or transistor 254a. Therefore, the system 200 illustrated in FIG. 2 allows four unique circuit shorts tests. A user can sequentially perform one or more of the unique circuit shorts tests as needed.

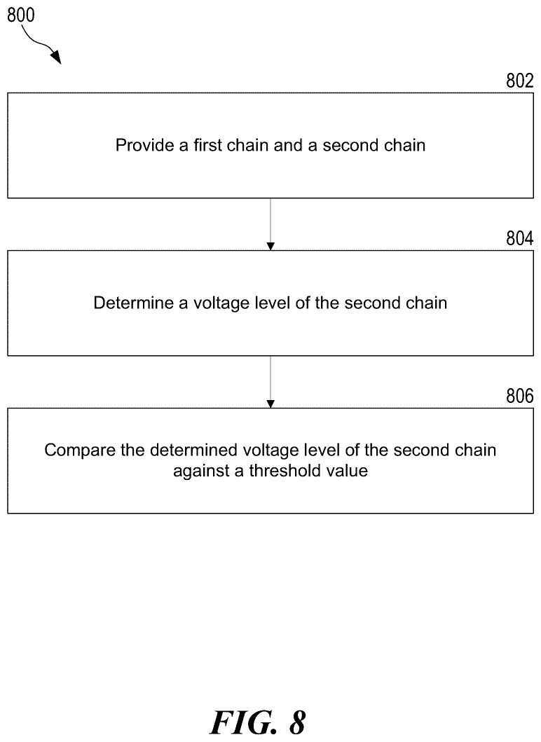

FIG. 8 is a flowchart illustrating a method 800 for testing for short circuiting in bonding between a first wafer and a second wafer in accordance with embodiments of the present technology. While the steps of the method 800 are described below in a particular order, one or more of the steps can be performed in a different order or omitted, and the method 800 can include additional and/or alternative steps. Additionally, although the method 800 may be described below with reference to the embodiments of the present technology described herein, the method 800 can be performed with other embodiments of the present technology.

The method 800 begins at block 802 by providing a first chain and a second chain. The first chain (e.g., Chain A of FIG. 2) can include a plurality of first dummy pads (e.g., the first dummy pads 240a) electrically connected to one another in series and to each of the first and second wafers (e.g., the first wafer 110 and the second wafer 120 of FIG. 1). The second chain (e.g., Chain B of FIG. 2) can include a plurality of second dummy pads (e.g., the second dummy pads 240b) electrically connected to one another in series and to each of the first and second wafers.

At block 804, the method 800 continues by determining a voltage level of the second chain. Determining can include (i) activating a first one of four CSA transistors (e.g., the transistors 256a, 256b, 258a, 258b), (ii) activating a second one of four CA transistors (e.g., the transistors 252a, 252b, 254a, 254b), and (iii) applying a ramp signal (e.g., vref) to a second input of a comparator (e.g., the comparator 266). The voltage level of the second chain can be determined based on an output of the comparator (e.g., Cmp_out).

At block 806, the method 800 continues by comparing the determined voltage level of the second chain against a threshold value. The threshold value can define the maximum expected voltage level of the second chain if there are no short circuiting issues. If the determined voltage level is below the threshold value, comparing can comprise determining that the first chain and the second chain are not short-circuited. If the determined voltage level is above the threshold value, comparing can comprise determining that the first chain and the second chain are short-circuited.

FIG. 10 illustrates a graphical user interface (GUI) 1000 that can configure the semiconductor interconnect verification system usage in accordance with embodiments of the present technology. The GUI 1000 can be an example GUI representing the configuration of semiconductor interconnect verification of the system 100 of FIG. 1 or the system 200 of FIG. 2, and can be displayable on the display 180 of FIG. 1. Also, although described herein as a graphical user interface, the GUI 1000 can instead be a printout or other medium for communicating information to a user.

The GUI 1000 includes a table with columns that list, in order from left to right, (i) a sub-feature parameter, (ii) options, (iii-x) inputs for data lines DQ0-DQ7, and (xi) notes. Referring first to the first sub-feature parameter P1, the rows associated therewith represent a lookup table listing input codes to control the semiconductor interconnect verification system. Based on the illustrated table, data lines DQ1-DQ4 can be used to select an operating mode of the semiconductor interconnect verification system. For example, different inputs can be applied to data lines DQ1 and DQ2 to select one of (i) the circuit resistivity verification test (FIGS. 3 and 4), the circuit leakage verification test (FIGS. 5 and 6), or the circuit shorts verification test (FIGS. 7-9). An input can be applied to data line DQ3 to select the particular chain to be tested (e.g., Chain A or Chain B). An input can be applied to data line DQ4 to select the various threshold values described herein (e.g., the lower threshold value associated with time t₄ in FIG. 3, the upper threshold value associated with time t₅ in FIG. 3, the threshold value associated with time t₄ in FIG. 5, and the threshold value associated with time t₄ in FIG. 7). For example, “time zero” can be selected to use threshold values provided by the supplier or manufacturer of the components, and “live” can be selected for the user to set custom threshold values as needed. The one or more threshold values can be stored in, e.g., a memory of a controller of the system, such as the controller 170 of FIG. 1 or the controller 270 of FIG. 2. An input can be applied to data line DQ0 to enable or disable the verification tests described herein.

Referring next to the second sub-feature parameter P2, the row associated therewith can display (e.g., dynamically) one or more of the threshold values being used. As discussed above, the threshold values displayed in the row of P2 can be threshold values provided by a supplier/manufacturer or the user. Referring next to the third sub-feature parameter P3, the row associated therewith can display (e.g., dynamically) one or more measured values corresponding to the threshold value(s) currently displayed in the row of P2. For example, if the semiconductor interconnect verification system is configured to test for circuit leakage in Chain A, as described in detail above with reference to FIGS. 5 and 6, the row of P2 can display the voltage threshold value associated with time t₄ in FIG. 5, and the row of P3 can display the measured voltage level retained by Chain A.

Referring next to the fourth sub-feature parameter P4, the row associated therewith can display (e.g., dynamically) the specific verification test performed (e.g., “Res” for the resistivity test, “Leak” for the leakage test, “Short” for the shorts test) and whether the circuit passed or failed that particular test. The result of the verification test can be based on a comparison between the values displayed on the row of P2 and the row of P3 as determined by, e.g., the controller 170 or 270.

Referring to FIGS. 2-10 together, the system 200 provides a single circuit layout that can be used to perform multiple different verification tests quickly and sequentially as desired. A user can apply various inputs according to a lookup table to easily choose between the different tests and/or change current flow paths. Also, the twisting or alternating arrangement of the dummy pads can enable the detection of short circuiting (or other issues) in multiple different directions, such as along a row, along a column, or diagonally. The results of the various verification tests can be used to quantify or otherwise gauge degradation of the WoW bonding or contact.

It will be appreciated that the system 200 is scalable and can be used to enable a smaller or a greater total number of verification tests. For example, in some embodiments, the system 200 can include more chains (and more associated dummy pads) and more transistors. Also, while each of Chain A and Chain B is illustrated in FIG. 2 as including a total of 10 dummy pads 240, in other embodiments, each of Chain A and Chain B (and additional chains, if any) can include fewer or more dummy pads 240. Different chains can include the same number of dummy pads 240 or different numbers of dummy pads 240.

### IV. Conclusion

It will be apparent to those having skill in the art that changes may be made to the details of the above-described embodiments without departing from the underlying principles of the present disclosure. In some cases, well known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

Where the context permits, singular or plural terms may also include the plural or singular term, respectively. For example, throughout this disclosure, the singular terms “a,” “an,” and “the” include plural referents unless the context clearly indicates otherwise. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, a step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

Reference herein to “one embodiment,” “an embodiment,” “some embodiments” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

Unless otherwise indicated, all numbers expressing numerical values used in the specification and claims, are to be understood as being modified in all instances by the term “about.” Accordingly, unless indicated to the contrary, the numerical parameters set forth in the specification and attached claims are approximations that may vary depending upon the desired properties sought to be obtained by the present technology. At the very least, and not as an attempt to limit the application of the doctrine of equivalents to the scope of the claims, each numerical parameter should at least be construed in light of the number of reported significant digits and by applying ordinary rounding techniques. Additionally, all ranges disclosed herein are to be understood to encompass any and all subranges subsumed therein. For example, a range of “1 to 10” includes any and all subranges between (and including) the minimum value of 1 and the maximum value of 10 (e.g., any and all subranges having a minimum value of equal to or greater than 1 and a maximum value of equal to or less than 10, such as 5.5 to 10).

The disclosure set forth above is not to be interpreted as reflecting an intention that any claim or example requires more features than those expressly recited in that claim or example. Rather, as the preceding examples and the following claims reflect, inventive aspects lie in a combination of fewer than all features of any single foregoing disclosed embodiment. Thus, the preceding examples and the following claims are hereby expressly incorporated into the Detailed Description, with each claim standing on its own as a separate embodiment. This disclosure includes all permutations of the independent claims with their dependent claims.

I/We claim:

1. A semiconductor interconnect verification system for testing bonding between a first wafer and a second wafer, the system comprising:
a plurality of first dummy pads electrically connected to one another in series to form a first chain, wherein the first dummy pads are arranged in pairs including a top dummy pad coupled to the first wafer and a bottom dummy pad coupled to the second wafer;
a plurality of second dummy pads electrically connected to one another in series to form a second chain, wherein the second dummy pads are arranged in pairs including a top dummy pad coupled to the first wafer and a bottom dummy pad coupled to the second wafer;
a current source configured to generate a current;
a comparator having a first input coupled to receive a ramp signal and a second input; and
a plurality of current source access (CSA) transistors including:
a first CSA transistor selectively coupling the current source to a first end of the first chain,
a second CSA transistor selectively coupling the current source to a first end of the second chain,
a third CSA transistor selectively coupling the current source to a second end of the first chain, and
a fourth CSA transistor selectively coupling the current source to a second end of the second chain; and
a plurality of comparator access (CA) transistors including:
a first CA transistor selectively coupling the second input of the comparator to the first end of the first chain,
a second CA transistor selectively coupling the second input of the comparator to the first end of the second chain,
a third CA transistor selectively coupling the second input of the comparator to the second end of the first chain, and
a fourth CA transistor selectively coupling the second input of the comparator to the second end of the second chain.

2. The system of claim 1, further comprising a plurality of ground access (GA) transistors including:
a first GA transistor selectively coupling the first end of the first chain to ground;
a second GA transistor selectively coupling the first end of the second chain to ground;
a third GA transistor selectively coupling the second end of the first chain to ground; and
a fourth GA transistor selectively coupling the second end of the second chain to ground.

3. The system of claim 1, wherein the first chain and the second chain are arranged in a twisting arrangement such that (i) first and second pairs of the first dummy pads are arranged adjacent to one another in a first row, (ii) first and second pairs of the second dummy pads are arranged adjacent to one another in a second row, (iii) third and fourth pairs of the first dummy pads are arranged adjacent to one another in the second row, and (iv) third and fourth pairs of the second dummy pads are arranged adjacent to one another in the first row.

4. The system of claim 3, wherein (i) the first and second pairs of the first dummy pads and (ii) the first and second pairs of the second dummy pads are arranged in the same columns, and wherein (i) the third and fourth pairs of the first dummy pads and (ii) the third and fourth pairs of the second dummy pads are arranged in the same columns.

5. The system of claim 3, wherein:
the first and second pairs of the first dummy pads are directly coupled together,
the second and third pairs of the first dummy pads are directly coupled together,
the third and fourth dummy pads of the first dummy pads are directly coupled together,
the first and second pairs of the second dummy pads are directly coupled together,
the second and third pairs of the second dummy pads are directly coupled together, and
the third and fourth dummy pads of the second dummy pads are directly coupled together.

6. The system of claim 1, further comprising a controller operably coupled to the plurality of CSA transistors and the plurality of CA transistors, wherein the controller is configured to (i) activate no more than one of the CSA transistors at a given time and (ii) no more than one of the CA transistors at a given time.

7. The system of claim 1, wherein an output of the comparator is usable as a proxy to determine a resistivity of the bonding between the first wafer and the second wafer.

8. The system of claim 1, wherein an output of the comparator is usable as a proxy to determine whether a leakage exists in the bonding between the first wafer and the second wafer.

9. The system of claim 1, wherein an output of the comparator is usable as a proxy to determine whether a short exists in the bonding between the first wafer and the second wafer.

10. A method for testing resistivity of bonding between a first wafer and a second wafer, the method comprising:
providing a first chain and a second chain, wherein the first chain includes a plurality of first dummy pads electrically connected to one another in series and to each of the first and second wafers, and wherein the second chain includes a plurality of second dummy pads electrically connected to one another in series and to each of the first and second wafers;
determining a voltage drop across the first chain, wherein determining comprises:
activating a first one of four current source access (CSA) transistors, wherein the first through fourth CSA transistors selectively couple a current source to (i) a first end of the first chain, (ii) a first end of the second chain, (iii) a second end of the first chain, and (iv) a second end of the second chain, respectively,
activating a first one of four comparator access (CA) transistors, wherein the first through fourth CA transistors selectively couple a first input of a comparator to (i) a first end of the first chain, (ii) a first end of the second chain, (iii) a second end of the first chain, and (iv) a second end of the second chain, respectively, and
applying a ramp signal to a second input of the comparator, wherein the voltage drop across the first chain is determined based on an output of the comparator; and
comparing the determined voltage drop across the first chain against a lower threshold value and an upper threshold value.

11. The method of claim 10, wherein comparing comprises:
determining that the determined voltage drop is between the lower threshold value and the upper threshold value; and
determining that the first chain is neither open nor short-circuited.

12. The method of claim 10, wherein comparing comprises:
determining that the determined voltage drop is below the lower threshold value; and
determining that the first chain is short-circuited.

13. The method of claim 10, wherein comparing comprises:
determining that the determined voltage drop is above the upper threshold value; and
determining that the first chain is open.

14. The method of claim 10, wherein the determined voltage drop is a first voltage drop across the first chain, and wherein the method further comprises:
determining a second voltage drop across the first chain, wherein determining comprises:
activating the third CSA transistor,
activating the third CA transistor, and
applying the ramp signal to the second input of the comparator, wherein the second voltage drop across the first chain is determined based on a second output of the comparator; and
comparing the determined second voltage drop across the first chain against the lower threshold value and the upper threshold value.

15. The method of claim 10, further comprising:
determining a voltage drop across the second chain, wherein determining comprises:
activating the second or fourth CSA transistor,
activating the second or fourth CA transistor, and
applying the ramp signal to the second input of the comparator, wherein the voltage drop across the second chain is determined based on a second output of the comparator; and
comparing the determined voltage drop across the second chain against the lower threshold value and the upper threshold value.

16. A method for testing for leakage in bonding between a first wafer and a second wafer, the method comprising:
providing a first chain and a second chain, wherein the first chain includes a plurality of first dummy pads electrically connected to one another in series and to each of the first and second wafers, and wherein the second chain includes a plurality of second dummy pads electrically connected to one another in series and to each of the first and second wafers;
determining a voltage level retained by the first chain, wherein determining comprises:
activating a first one of four current source access (CSA) transistors, wherein the first through fourth CSA transistors selectively couple a current source to (i) a first end of the first chain, (ii) a first end of the second chain, (iii) a second end of the first chain, and (iv) a second end of the second chain, respectively,
deactivating the first CSA transistor,
activating a first one of four comparator access (CA) transistors, wherein the first through fourth CA transistors selectively couple a first input of a comparator to (i) a first end of the first chain, (ii) a first end of the second chain, (iii) a second end of the first chain, and (iv) a second end of the second chain, respectively, and
applying a ramp signal to a second input of the comparator, wherein the voltage level retained by the first chain is determined based on an output of the comparator; and
comparing the determined voltage level retained by the first chain against a threshold value.

17. The method of claim 16, wherein comparing comprises:
determining that the determined voltage level is below the threshold value; and
determining that the first chain has a leakage.

18. The method of claim 16, wherein comparing comprises:
determining that the determined voltage level is above the threshold value; and
determining that the first chain does not have a leakage.

19. The method of claim 16, wherein the determine voltage level is a first voltage level retained by the first chain, and wherein the method further comprises:
determining a second voltage level retained by the first chain, wherein determining comprises:
activating the third CSA transistor,
activating the third CA transistor, and
applying the ramp signal to the second input of the comparator, wherein the second voltage level retained by the first chain is determined based on a second output of the comparator; and
comparing the determined second voltage level retained by the first chain against the threshold value.

20. The method of claim 16, further comprising:
determining a voltage level retained by the second chain, wherein determining comprises:
activating the second or fourth CSA transistor,
activating the second or fourth CA transistor, and
applying the ramp signal to the second input of the comparator, wherein the voltage level retained by the second chain is determined based on a second output of the comparator; and
comparing the determined voltage level retained by the second chain against the threshold value.

21. A method for testing for short circuiting in bonding between a first wafer and a second wafer, the method comprising:
providing a first chain and a second chain, wherein the first chain includes a plurality of first dummy pads electrically connected to one another in series and to each of the first and second wafers, and wherein the second chain includes a plurality of second dummy pads electrically connected to one another in series and to each of the first and second wafers;
determining a voltage level of the second chain, wherein determining comprises:
activating a first one of four current source access (CSA) transistors, wherein the first through fourth CSA transistors selectively couple a current source to (i) a first end of the first chain, (ii) a first end of the second chain, (iii) a second end of the first chain, and (iv) a second end of the second chain, respectively,
activating a second one of four comparator access (CA) transistors, wherein the first through fourth CA transistors selectively couple a first input of a comparator to (i) a first end of the first chain, (ii) a first end of the second chain, (iii) a second end of the first chain, and (iv) a second end of the second chain, respectively, and
applying a ramp signal to a second input of the comparator, wherein the voltage level of the second chain is determined based on an output of the comparator; and
comparing the determined voltage level of the second chain against a threshold value.

22. The method of claim 21, wherein comparing comprises:
determining that the determined voltage level is below the threshold value; and
determining that the first chain and the second chain are not short-circuited.

23. The method of claim 21, wherein comparing comprises:
determining that the determined voltage level is above the threshold value; and
determining that the first chain and the second chain are short-circuited.

24. The method of claim 21, further comprising:
determining a voltage level of the first chain, wherein determining comprises:
activating the second or fourth CSA transistor,
activating the first or third CA transistor, and
applying the ramp signal to the second input of the comparator, wherein the voltage level of the first chain is determined based on a second output of the comparator; and
comparing the determined voltage level of the first chain to the threshold value.
